(19) United States
(12) Patent Application Publication
(10) Pub. No.: US 2012/0176243 A1
(43) Pub. Date: Jul. 12, 2012

(54) CABLE, SHEATH, AND SYSTEMS

(75) Inventor: Jacob Andersen, Liberty Lake, WA (US)

(73) Assignee: Andersen Holdings, LLC, Liberty Lake, WA (US)

(21) Appl. No.: 12/986,552

(22) Filed: Jan. 7, 2011

(51) Int. Cl. G08B 13/22; G01N 21/84; G01R 31/02

(52) U.S. Cl. 340/568.1; 324/543; 324/539; 356/73.1; 324/542

(57) ABSTRACT

Disclosed herein are cables, cable systems, security systems, and detection components. According to an implementation, a cable may have a first portion and a second portion. The second portion may be further distant from a central axis of the cable than the first portion. The second portion is configured to provide notification when the second portion has been damaged or severed. The second portion may be a sheath and the first portion a pre-existing or conventional cable or wire such that the sheath provides notification when the sheath has been damaged or severed prior to the underlying cable or wire being damaged or severed.

### BACKGROUND

Conventional cables such as security cables, electrical cables, fiber optic cables and the like and cable systems that incorporate those cables have no way to automatically provide notification of damage to the cable. Thus, if a portion of the cable is damaged, there is typically no knowledge of the damage until some catastrophic event occurs or until the cable is manually inspected for damage. Damage may be caused by a cutting action or may be the result of incidental wearing or cutting, such as if the cable is struck during a digging process or if excessive wear occurs due to environmental effects. Manual inspection may not be practical, particularly where security, safety, or reliability are involved or in instances where long lengths of cable are being monitored.

Using an example, cables and locking mechanisms are often used to deter theft of an item secured with the cable and locking mechanism. Typically, the cable is wrapped around an object and secured using the locking mechanism. Some conventional cables and locking mechanisms are designed to notify a property owner of a complete cable breach or lock breach that has been made. For example, U.S. Pat. No. 7,274,293 utilizes a cable locking system with an alarm trigger wire to activate the security system when the cable is cut entirely through. In certain instances, such as when the item is a mobile item, like a tool box or a bicycle, once the cable is cut, the thief may relatively immediately leave the area where the locking mechanism and/or cable are located. Thus, the notification would likely be delivered too late to the owner of the item, to a custodian of the item, or to a watchman, security officer, or other law enforcement official to be effective in preventing the theft. The notification would also likely come too late to allow the owner or custodian or law enforcement officer to return to the location of the item or otherwise deter the theft prior to the cable being completely cut through.

### BRIEF DESCRIPTION OF DRAWINGS

FIG. 1 is a schematic cut-away view of an exemplary cable for detecting a wearing or cutting of the cable.

FIG. 2 is a schematic view of an exemplary cable system for detecting a wearing or cutting of the cable.

FIG. 3 is a schematic view of a security system according to a security cable implementation.

FIG. 4A is a schematic diagram of a security cable system that may be used in the security system shown in FIG. 3.

FIG. 4B is a schematic diagram of a security cable system according to an implementation.

FIG. 4C is a schematic diagram of a security cable system according to an implementation.

FIG. 5 is a schematic diagram of an example electrical circuit that may be used in the cable system of FIG. 2.

FIG. 6 is a schematic cut-away view of an exemplary cable for detecting a wearing or cutting of the cable.

FIG. 7 is a schematic cut-away view of an exemplary sheath for detecting a wearing or cutting of the sheath prior to damage of an underlying cable component.

In the following detailed description, reference is made to the accompanying schematic drawings, which form a part hereof. The use of the same symbols in different drawings typically indicates similar or identical items. The illustrative embodiments described in the detailed description, drawings, and claims are provided merely for illustration and are not meant to be limiting. Other embodiments may be utilized, and other changes may be made, without departing from the spirit or scope of the subject matter presented here.

### DETAILED DESCRIPTION

The present disclosure provides cables, sheaths, cable systems, security cable systems, and security systems. While examples of these are described for purposes of convenience of understanding, the disclosure is not intended to be limited by the exemplary descriptions provided herein.

According to an implementation, a cable is disclosed having a central axis, a first portion, and a second portion. The second portion is further distant from the central axis of the cable than the first portion. The second portion is configured to provide notification when the second portion has been damaged. The cable may be provided such that it provides a notification of damage to the second and outer portion of the cross-section of the cable system prior to severance of the inner first portion. The first portion may be a security cable component, an electricity transmission cable component, fiber optic cable component, or other similar cable implementation. The second portion may be provided on or around the first portion and may utilize electric wires or fiber optic strands to detect wearing or cutting of the cable. Moreover, the second portion may extend along a portion or the entire length of the cable.

According to an implementation, a cable system includes a cable and a monitoring component. The monitoring component may sense damage to the cable prior to severance of the cable. The cable has a central axis, a first portion, and a second portion. The second portion may be further distant from the central axis of the cable than the first portion. The second portion may be monitored by the monitoring component to monitor when the second portion has been damaged or severed.

According to an implementation, a sheath is provided that is configured to fit around a cable component. The sheath utilizes one or more detection components to provide notification that the sheath has been damaged. The damage may be repaired or addressed, and/or an alarm may be activated, prior to damage, particularly catastrophic damage, occurring to the underlying cable component.

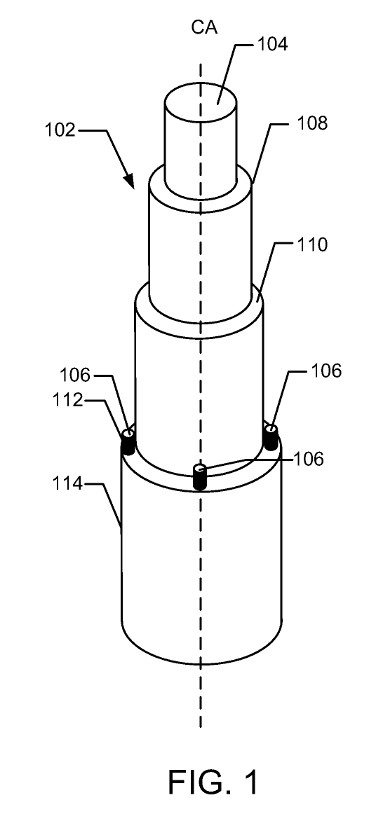

FIG. 1 shows a cutaway view of an exemplary cable 102. According to this implementation, the cable 102 may have multiple layers or portions generally including at least one central cable component 104, such as a security cable, electrical transmission cable or wire, or fiber optic cable or bundle, and at least one detection component 106, such as an electrical wire or fiber optic cable. While FIG. 1 shows a single cable or wire for the cable component 104 and three electrical wire detection components 106, the implementation is not so limited. Any number of cables or wires may be utilized as the cable component 104 as may be required for strength, in the case that the cable 102 is used as a security cable, or for necessary communication of electrical or optical signals, in the case where the cable 102 is used for an electric signal cable or a fiber optic cable. Similarly, the number and placement of detection components 106 may be adjusted based on the application and other design considerations. Moreover, cable component 104 and detection component 106 are shown extending only in a longitudinally linear fashion. However, in the case that multiple cables or wires are utilized for wither or both of the cable component 104 and/or detection component 106, the individual wires or cables may be twisted, braided, or otherwise aligned and/or intertwined. Moreover, the cable component 104 and/or detection component 106 may extend along a portion or the entire length of cable 102. The cable component 104 may be have any predetermined level of flexibility or rigidity and may be implemented as a shaped or straight rigid bar.

According to the implementation shown in FIG. 1, at least one detection component 106 is further distant from the central axis CA of the cable system 102 than at least one cable component 104. Thus, as an attempt is made to cut the cable system 102, or as environmental wear occurs on the cable system 102, the at least one detection component 106 is cut prior to the cable component 104. The cable component 104 and the detection component 106 may each or both provide tensile and/or shear strength to the cable system 102. Moreover, either or both of the cable component 104 and the detection component 106 may be configured for monitoring. Thus, a change in an electrical property (or light, in the case of fiber optic cable) of the detection component 106 and, in certain implementations, cable component 104, due to a cut, wear, or shearing may be used to detect damage to the cable 102 prior to catastrophic failure of the cable 102.

Cable 102 may further comprise a cut resistant layer such as a fibrous core supplement 108 to further prevent or delay catastrophic wearing, shearing, or cutting, particularly of the cable component 104. The fibrous core supplement 108 may include one or more metal layers or components such as a titanium, stainless steel, etc. and/or a fibrous material such as Kevlar™, available from the Dupont Corporation of Wilmington, Del. or a thermoplastic polyethelene or nylon material. A vinyl, plastic, or other coating 110 may be optionally provided around the core components (e.g. the cable component(s) 104, core supplement 108, etc.).

The one or more detection components 106 may be provided in around or along fibrous core supplement 108 or coating 110. If implemented as one or more electrical wires, detection component 106 may have an electrically insulating coating 112 to isolate or shield adjacent electrical wires from each other and from any surrounding environment. If implemented as one or more fiber optic cables, detection component 106 may have a light reflecting or shielding coating 112 to isolate or shield adjacent fiber optic cables from each other and from any surrounding environment. Additionally or alternatively, the one or more detection components 106 may be encased or encapsulated by a protective layer 114. The protective layer 114 may be constructed of a common flexible or rigid cable covering including conventional types of plastic, vinyl, rubber compounds, cut resistant materials or other suitable materials.

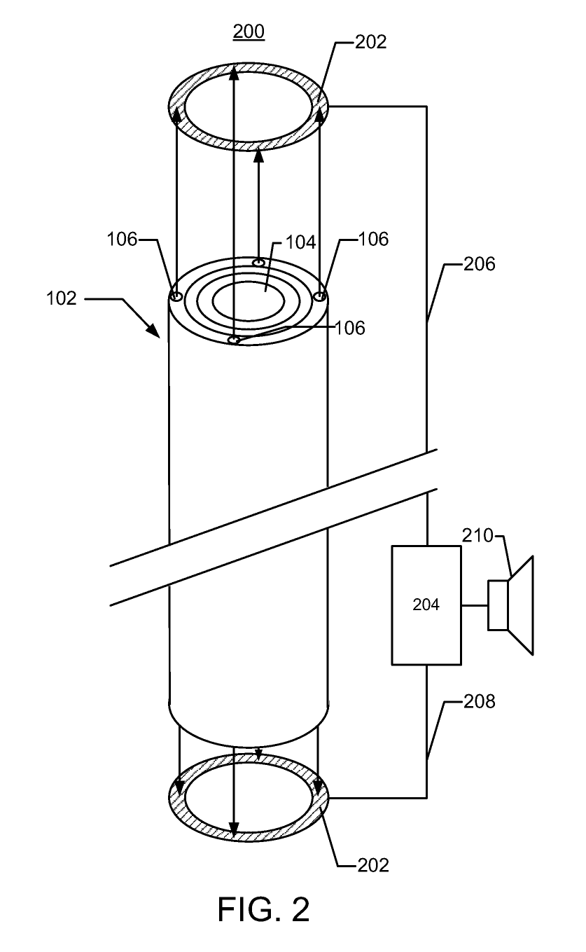

FIG. 2 shows an exemplary cable monitoring system 200, including a cable 102, one or more contacts 202, and a monitoring component 204 for monitoring a characteristic associated with the electrical wire detection components 106 by coupling the monitoring component 204 to the electrical wire detection components 106 via electrical connections 206 and 208. According to the implementation, the monitoring component 204 provides a voltage or current to the one or more electrical wires 106 and monitors an electrical characteristic of the electrical wire(s) 106 resulting from the applied voltage or current. The monitoring component 204 may include or be connected to an alarm component 210, which may provide a visible, audible, or other sensory alarm locally and/or remotely to indicate that monitoring component 204 has detected a change with respect to one or more of the electrical wire detection components 106.

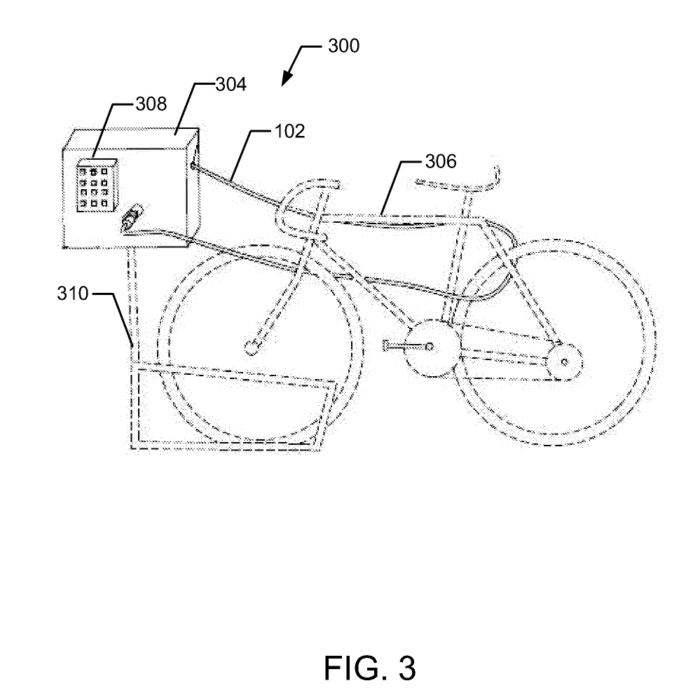

Cable monitoring system 200 may be best understood using an example involving a would-be thief attempting to steal an item protected by the cable 102 or, more particularly, by the security system 300, shown in FIG. 3. Security system 300 may include the cable monitoring system 200 and a locking mechanism 304. The monitoring component 204 (shown schematically in FIG. 2, not shown in FIG. 3) may be housed within or around the locking mechanism and/or the cable in order to monitor the cable 102.

According to the implementation shown in FIG. 3, security system 300 may secure, protect, and/or prevent the theft of an item 306, such as a bike, as shown in FIG. 3. As is described herein, the cable 102 is configured to interface with a monitoring component 204 and an alarm component 210, as shown by way of example in FIGS. 2, to provide notification in the event that the cable 102 is attempted to be cut even if the cut attempt is not completed. The locking mechanism 304 may ensure that the cable 102 is securely fastened around or through the item 306. Moreover, the locking mechanism 304 may generally ensure that the item 306 may not be removed unless the locking mechanism 304 is opened, disabled, destroyed, or the cable 102 is cut.

The locking mechanism 304 may be opened or disabled using a user interface 308, such as a touch screen, keypad, dial, or other suitable interface operable to allow a user to enter a code, combination, or other input that authorizes or allows the user to open or disable the locking mechanism 304. The locking mechanism 304 may be permanently or semi-permanently affixed to a structure 310 which may, in turn, be permanently or semi-permanently affixed to another surface, such as a floor, earthen surface, concrete slab, asphalt surface, building structure or other suitable affixable surface.

When the would-be thief attempts to shear or cut the cable 102, one or more of the electrical wire detection components 106 is cut or damaged prior to the cable 102 experiencing a catastrophic failure. The monitoring component 204, shown in FIG. 2, senses the breach of one or more of the electrical wire detection components 106 and actives a local and/or remote alarm during a relatively early stage of the cutting activity. The alarm alerts the would-be thief, the owner/custodian of the item, a law enforcement official, and/or any other interested or available person or party. The local and/or remote alarms encourage the would-be thief to abandon the pursuit prior to freeing the object secured by the security cable component 104, (shown in FIGS. 1 and 2) which may be a steel reinforcing cable selected based on its cut resistance and strength. Should the would-be thief continue to try to continue to cut the cable 102 after the alarm component 210 has been activated, the alarm may draw the attention of the owner/custodian, law enforcement official, or passers-by to the continued attempts.

According the exemplary implementations shown in FIGS. 1-3, a cable 102 used to secure an item would advantageously require several cut attempts and tool realignments in order to complete the theft. This is so because the implementations described herein may cause conventional cutters, which rely on pinching, to get caught up on the vinyl or plastic layer 108, the underlying fibrous core supplement layer 108, and or the cable component 104. This may necessitate multiple attempts with a conventional cutter to fully cut the cable 102 in addition to requiring a sharp edge, such as a knife, to additionally sever the fibrous layer 108, which may be pinch resistant.

According to an implementation, the electrical wire detection components 106 are provided on or near a peripheral region of the cable 102 so that the alarm is activated during the first stage of the first cutting attempt. In the case of an alarm that is in the local proximity of the cable 102, the would-be thief would have to continue cutting despite the visual and/or audible indicators of the alarm calling attention to the act. In the case of a silent alarm or an additional remote alarm notifying the owner/custodian, law enforcement official, and/or other interested party, the early activation would allow the owner/custodian, law enforcement, and/or other interested party to approach the location while the would-be thief is still attempting to cut the cable 102. The likelihood of catching or discouraging the thief is thereby enhanced.

According to a further implementation, the monitoring component 204 may be coupled to control a security device, such as a security camera, (not shown) to activate an automated response such as activating a security camera to take photos or video of the thief performing the act. Such an implementation may be combined with the alarm such that a visual and or audible alarm is triggered, a security camera is activated, and/or a security guard is notified.

Although the cable 102 has been described using the example implementation of a security cable of FIG. 3, the cable 102 could similarly be used for a communication cable, such as an electrical cable or wire or a fiber optic cable or wire. Thus, the cable component 104 may be a conventional cable used to transmit electrical or light signals. The detection components 106 may detect damage or wear to the wire cable 102 prior to damage to cable component 104. Thus, if excessive wear or a cut is detected to detection components 106, the cable 102 may be inspected or otherwise addressed by the cable owner, user, or maintainer prior to damage occurring to the underlying cable component 104. Such early detection may prevent any signal loss across the electrical or fiber optic cable component 104. Moreover, such early detection may prevent fire or electrocution dangers that would be caused if the electrical cable component 104 were exposed or cut.

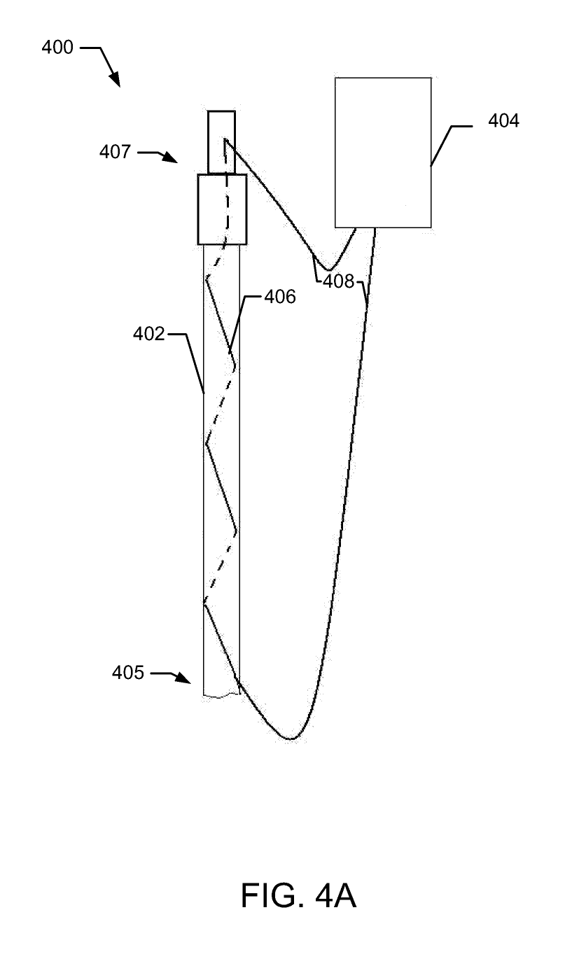

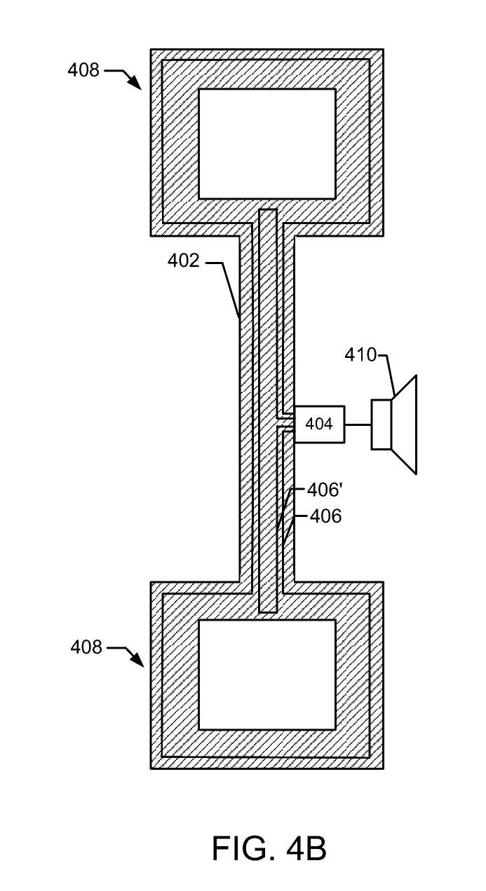

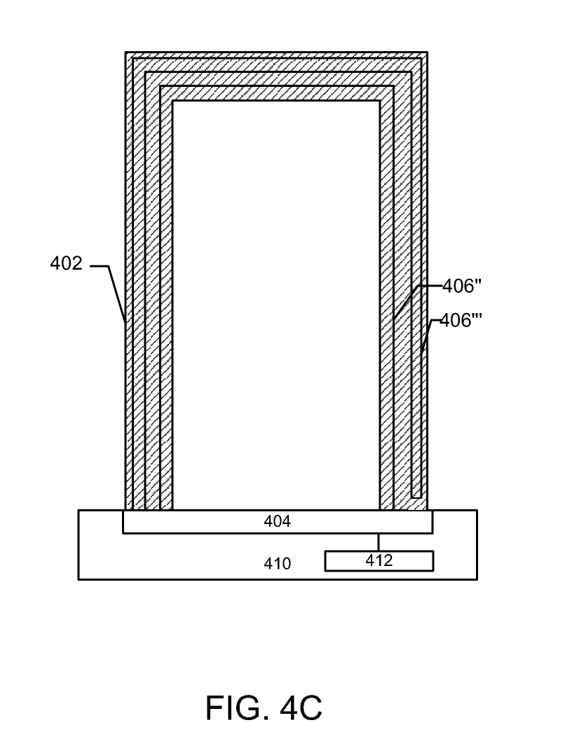

FIG. 4A shows an implementation of a security cable system 400. The security cable system 400 includes a cable 402 and a monitoring component 404 coupled to an electrical wire detection component 406 via electrical wiring 408. Using the example security system 300 shown in FIG. 3, cable 402 may be used as cable 102 and monitoring component 404 may be included in, on, or otherwise associated with the locking mechanism 304. Monitoring component 404 may alternatively be implemented independently of any locking mechanism. A first end 405 of cable 404 may be secured to the locking mechanism 304. A second end 407 may be releasably secured to the locking mechanism 304 to facilitate wrapping the cable 404 around an item 306.

The monitoring component 404 may be configured to sense an attempt to cut cable 402. As described with respect to FIGS. 1-3, the cable 402 may have one or more security cable components 104 and surrounding layers (core supplement 108, covering 110, protective layer 114, and so forth) to reduce the likelihood of a single cutting attempt being successful. One or more electrical wire detection components 406 may be provided further from the central axis of the cable 402 than at least one of the security cable component(s). For example, as shown in FIG. 4A, electrical wire detection component 406 maybe helically wound around or near the perimeter of the cable 402. Each of the two ends of the electrical wire detection component 406 is connected in an electrical circuit monitored by the monitoring component 404, where the electrical circuit may include wires 408 to couple the electrical wire detection component 406 to the monitoring component 404. If an attempt is made to cut or shear the cable 402, electrical wire detection component 406 is severed before the underlying reinforcement wires, layers, and/or cable components of cable 402. The monitoring component 404 may sense that the circuit formed between the monitoring component 404 and the electrical wire detection component 406 is disturbed and may remotely notify the owner of the item, a custodian of the item, or other interested party, and/or may initiate an audible, visible, or other sensory alarm locally to deter further cutting attempts via alarm component 410.

As mentioned above, the detection component may extend helically or linearly along the cable. In the event that the cable is configured to include multiple electrical wire detection components to be monitored by the monitoring component, the electrical wires may be placed in a number of configurations. For example, one or more of the electrical wires may be twisted, spiraled, coiled, or helically wound along the length of the cable. Additionally or alternatively, one or more of the electrical wires may extend generally linearly along the cable, as shown in FIGS. 1, 2 and 4B. One or more circuits may thus be made with electrical wire detection components 406 running along the length of the cable 402. Although only two exemplary circuits are shown in FIG. 4B (406 and 406′) for the sake of simplicity, additional circuits may be included. Moreover, the cable component (not shown) may also be monitored by the monitoring component 404 so that the system can additionally detect when the cable 402 is completely cut and therefore no longer securing the item of interest.

One skilled in the art will appreciate that the wiring configuration shown in FIG. 4B may be modified on an application specific basis. For example, electrical wires 406 are shown as extending around the cable loops 408, which may be configured to accept a locking mechanism, such as a padlock, U-lock or other suitable lock. However, as illustrated with electrical wire 406′, the electrical wire detection component 406 the need not extend around loops 408, particularly in the case where only one loop 408 or no loops are included on the cable 402. Moreover, as shown in FIG. 4C, the monitoring component 404 may interface with cable 402 at any point along the cable 402 and may interface with the electrical wire, e.g. electrical wire detection component 406″, at both ends of the cable 402. Additionally or alternatively, the electrical wire detection component 406, e.g. electrical wire 406′″, may interface with only one end of cable 402. Such configurations may be particularly desirable in an instance in which the monitoring component 404 is integrated in or on a locking mechanism 410 or where the cable 402 is implemented as a rigid or semi-rigid bar.

According to the implementation shown in FIG. 4C, a first end of the cable 402 has a first contact for connecting a first end of one or more electrical wires 406″ and/or 406′″ to a first sensing portion or contact of the monitoring component 404. A second end of the cable 402 may additionally have a second contact (i.e., in the case of 406″) for connecting a second end of one or more of the electrical wires 406″ to a second end of the monitoring component 404. The second end of the cable 402 may be a free end. Additionally or alternatively, an end of the cable 402 may be provided with an attachment device for attaching to a locking mechanism as shown in FIGS. 3, 4A and 4B. Additionally or alternatively, an end of the cable 402 may have one or more looped ends as shown in 4B.

According to an implementation, the monitoring component 204 (or 404) may be activated and monitored locally at the location of the item and cable, or may be activated and/or monitored remotely using a software and/or hardware interface to sensing the integrity of the electrical wires detection component(s), e.g. 106.

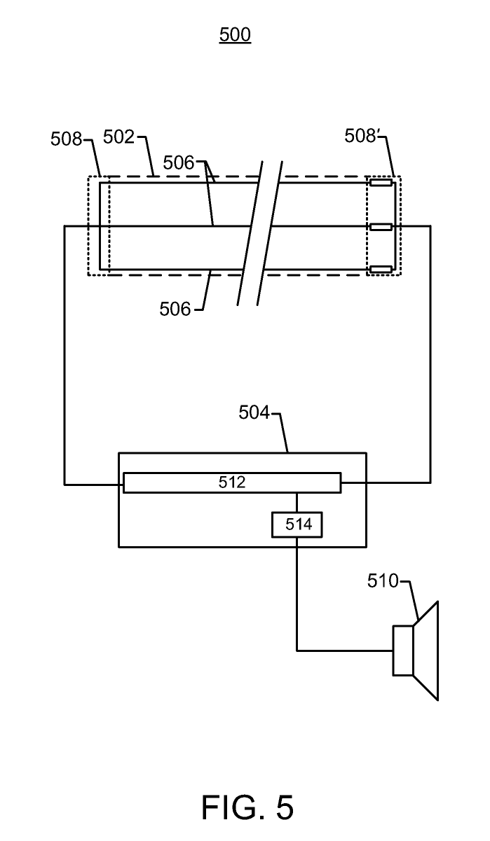

FIG. 5 shows an example circuit 500 implemented with a cable 502 (shown in dashed line). A monitoring component 504 may be utilized to monitor electrical wire implemented detection components 506 placed within or upon cable 502. The monitoring component 504 may be coupled to detection components 506 via contacts 508 and 508′ (shown in dotted lines). The monitoring component 504 measures the resistance of the circuit loop, whether it be a single loop or a parallel sum of resistances for more than one loop.

According to one implementation, the monitoring component 504 measures resistance using analog techniques. According to this implementation, a “latched” condition may be created for each of the detection components 506 that are part of the circuit. The detection components 506 may be coupled with an analog relay, which provides a relatively constant system resistance. When one of the detection components 506 is severed, that detection component 506 creates an “unlatched” state which is sent through component 512, which may be a relay, to a processing component 514, such as a processor or other suitable mechanism associated with monitoring component 504. The processor 514 senses the change in resistance caused by the “unlatched” state of the detection component 506, which may in turn cause the alarm component 510 to be triggered.

According to an alternative implementation, the monitoring component 504 measures resistance using digital techniques. According to this implementation, a “latched” condition may be created for each of the detection components 506 that are part of the circuit. The detection components 506 may be coupled to provide a relatively constant system resistance. When one of the detection components 506 is severed, that detection component 506 creates an “unlatched” state which is sent through component 512, which may be an analog to digital (A-D) converter, to a processing component 514, such as a processor or other suitable mechanism associated with monitoring component 504. The A-D converter of component 512 may generate digital output reflecting the system resistance. The processor 514 senses a change in the digital value output by the A-D converter caused by the “unlatched” state of the detection component 506, which may in turn cause the alarm component 510 to be triggered.

The circuit 500 may also be an analog/digital circuit that senses the resistance of the alarm circuit or the continuity of the alarm wire(s) and generates one or more data formats of digital output with information about the state of the detection components 506. For example, component 512 may be a analog/digital converter that senses the state of the detection components 506, where a resistance of a certain value will yield digital output 0000. The processor may continuously or at chosen intervals check the digital output from the A-D converter and match it to a pre-programmed threshold or thresholds. The digital output of the A-D converter changes based on the number of detection components 506 that have been cut or damaged and, in response to such an event, the A-D converter gives the programmed data or alarm response to a computer or monitoring system for further processing or to trigger additional responses.

Additionally or alternatively, the circuit 500 may be fully digital and controlled by a remote or host computer (not shown) that monitors the resistance or integrity of each wire detection component 506. The resistance wires may be sensed to generate output data. The data may be multiplexed and formatted to be sent via one or more digital formats by either wired of wireless data transfer to a remote computer or monitor system where the remote system determines the integrity of the electrical wire detection components 506.

The processor 514 may be configured to sense threshold values such that a different alarm or notification may be provided based on the number of detection components that have been severed. Additionally or alternatively, the processor 514 may be programmed to “disable” or ignore the effects of a faulty detection component 506. Additionally or alternatively, the processor 514 may be programmed to ignore minor changes or short term changes in resistance, capacitance, voltage, current, or other electrical characteristic including data transmitted. The processor 514 may output a signal to an alarm, communication device, remote and/or mobile device, other computer and so forth.

The monitoring component 504 may monitor the integrity of the electrical wire detection components 206 by continuously measuring conductivity, resistance, or other electrical characteristic of each individual wire circuit or by measuring the conductivity, resistance, or other electrical characteristic of each individual wire detection component 506 compared to a common conductor, such as a center steel cable. The monitoring component 504 may direct the alarm component 510, such as a local alarm, security information alarm system, site security, and/or remote monitoring system, that the exterior integrity of the cable 502 has been compromised-due to a breach of one or more of the electrical wire detection components 506—thus triggering an alarm or notification condition. The alarm component 510 may provide (or cause to be provided) a visible alert, an audible alert, or both, to an area proximate to the cable. Additionally or alternatively, the alarm may be a visible and/or audible alert provided to the owner/custodian of the item, to a security guard, to a law enforcement official, cable maintainer, or other interested party.

An alternative implementation may be understood with regard to FIGS. 1 and 2. According to this implementation, the one or more detection components 106 may be implemented as fiber optic cables. The monitoring component 104 may sense or detect a characteristic of light traveling through the fiber optic cable detection components 106. The monitoring component 204 may be configured to provide notification if a change in the characteristic of the light is detected. The light passing through fiber optic cable detection components 106 may be generated by the monitoring component 204 or may be provided by another source as will be appreciated by one skilled in the art.

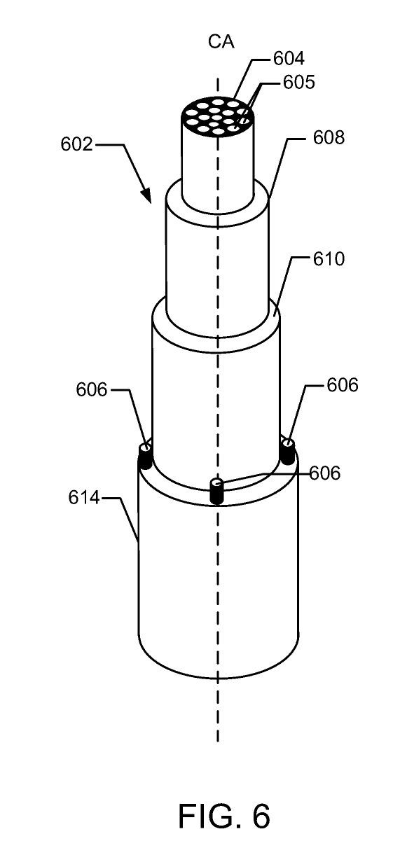

FIG. 6 shows an implementation of a cable 602 in which a cable component 604 comprises multiple sub-components 605, which may be wires, cables, or other suitable subcomponents. The subcomponents 605 may be provided in a longitudinally aligned fashion. For example, the subcomponents 605 may extend relatively parallel to the central axis CA or may be twisted, wound, braided or otherwise intertwined and/or aligned to form cable component 604.

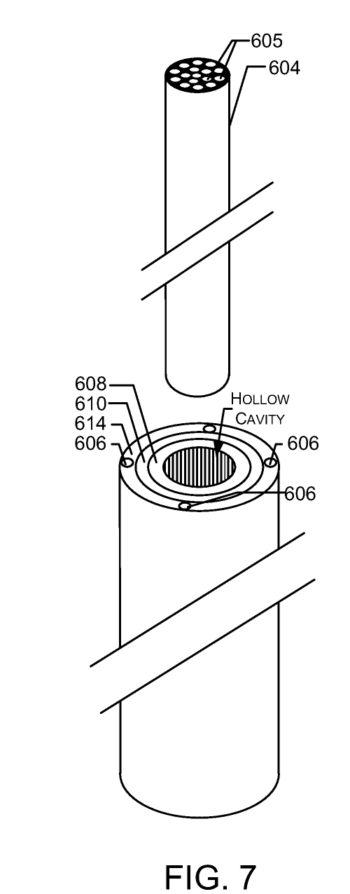

According to an implementation, the cable component 604 may be provided as a conventional cable or wire, such as a conventional or pre-existing fiber optic cable or bundle, electricity transmission cable or bundle, security cable, or the like. Detection components 606, which may be similar to detection components 106, 406 and/or 506, may be formed or otherwise provided around the cable component 604. For example, as illustrated in FIG. 7, the detection components 606 may be provided as part of a sheath 614 that may be pulled over, pushed around, or formed upon the cable component 604. Intermediate layers, such as a cut/pinch resistant layer 608 and/or a coating 610 may additionally be provided to protect the cable component 604. Layers 608 and 610 may be applied to the cable component 604 prior to the application of the sheath 614 or they may be optionally provided within sheath 610 as shown in FIG. 7. The sheath 610 and detection components 606 could be used consistent with the other implementations described herein in order to provide notification when the detection components have been damaged. Thus, by utilizing one or more detection components 606, the sheath 614 provides notification when the sheath 614 has been damaged. The damage may be repaired or addressed, and/or an alarm may be activated, prior to damage, particularly catastrophic damage, occurring to the underlying cable, e.g. cable component 604.

### CONCLUSION

Undoubtedly, numerous variations and modifications of the invention will become readily apparent to those familiar with cables and electrical monitoring systems. Although implementations of the cable and monitoring systems have been described in language specific to structural features and/or methodological acts, it is to be understood that the system and method defined in the appended claims is not necessarily limited to the specific features or acts described. Rather, the specific features and acts are disclosed as exemplary forms of implementing the claims.

What is claimed is:

1. A cable having a central axis, the cable comprising:
a first portion; and
a second portion further distant from the central axis of the cable than the first portion, the second portion configured to provide notification when the second portion is damaged.

2. The cable of claim 1, further comprising a cut-resistant or wear-resistant layer between the first portion and the second portion.

3. The cable of claim 1, wherein the second portion comprises one or more electrical wires connected in a circuit with a monitoring component, the monitoring component configured to sense a change in the circuit due to damage to the one or more electrical wires.

4. The cable of claim 3, wherein the one or more electrical wires extend helically around a perimeter of the cable.

5. The cable of claim 1, wherein the second portion comprises a plurality of electrical wires connected in parallel in a circuit with a monitoring component, the monitoring component configured to sense a change in the circuit due to damage to the one or more electrical wires.

6. The cable of claim 1, wherein the second portion comprises one or more fiber optic cables connected to a monitoring component, the monitoring component configured to sense a change in a light characteristic due to damage to the one or more fiber optic cables.

7. The cable of claim 1, wherein the first portion is a security cable, a fiber optic cable, or an electricity transmission cable.

8. A cable system comprising:
a cable; and
a monitoring component configured to determine whether an outer portion of the cross-section of the cable has been damaged or severed.

9. The cable system according to claim 8, wherein the cable comprises one or more detection components extending along the longitudinal direction of the cable, wherein the one or more detection components is provided on a perimeter region of the cable, and wherein the monitoring component is configured to detect that at least one of the one or more detection components is damaged or severed.

10. The cable system of claim 8, wherein the monitoring component is configured to activate an alarm component.

11. The cable system of claim 10, wherein the alarm component activates a visible alarm, an audible alarm or both a visible alarm and an audible alarm in a region local to the cable.

12. The cable system of claim 10, wherein the alarm component activates a visible alarm, an audible alarm or both a visible alarm and an audible alarm in a region remote from the cable.

13. The cable system according to claim 9, wherein the cable further comprises one or more cable components, and wherein at least one of the one or more detection components is further distant from a central axis of the cable than at least one of the one or more cable components.

14. The cable system according to claim 13, wherein the cable component is a security cable, the cable further comprising a cut resistant layer between the one or more detection components and the security cable.

15. A security system comprising:
a cable configured to wrap around or through an item,
a locking mechanism to secure the cable around or through the item;
a monitoring component configured to determine whether an outer portion of the cable has been damaged; and
an alarm component configured to indicate that the outer portion of the cable has been damaged.

16. The security system according to claim 15, wherein the cable comprises one or more electrical wires extending along the longitudinal direction of the cable, wherein the one or more electrical wires are provided on a perimeter region of the cable, wherein the one or more electrical wires are provided as one or more electrical circuits with the monitoring component, wherein the monitoring component is configured to detect at least one of the one or more electrical wires being severed or damaged, and wherein the monitoring component is configured to direct the alarm component to activate an alarm when the monitoring component detects at least one of the one or more electrical wires has been severed.

17. The security system according to claim 16, wherein the cable further comprises one or more security cable components, and wherein at least one of the one or more electrical wires is further distant from a central axis of the cable than at least one of the one or more security cable components.

18. The cable system according to claim 17, further comprising a cut resistant layer between the one or more electrical wires and the security cable component.

19. The security system of claim 15, wherein the alarm component provides an audible or visible alert to an area proximate to the cable.

20. The security system of claim 15, wherein the alarm component notifies an owner or custodian of the item.

21. A sheath configured to fit around a cable component, the sheath comprising at least one detection component to provide notification when the detection component of the sheath is damaged.
